(19) United States
(12) Patent Application Publication
(10) Pub. No.: US 2026/0100493 A1
(43) Pub. Date: Apr. 9, 2026

(54) N-WAY COUPLER AND CHIP INCLUDING THE SAME

(71) Applicant: SAMSUNG ELECTRONICS CO., LTD., Suwon-si (KR)

(72) Inventors: GeonHo PARK, Suwon-si (KR); Kyunghwan KIM, Suwon-si (KR); Byeongtek MOON, Suwon-si (KR); Hyunchul PARK, Suwon-si (KR); Sangmin YOO, Suwon-si (KR); Joonhoi HUR, Suwon-si (KR)

(73) Assignee: SAMSUNG ELECTRONICS CO., LTD., Suwon-si (KR)

(21) Appl. No.: 19/352,053

(22) Filed: Oct. 7, 2025

(30) Foreign Application Priority Data
Oct. 8, 2024 (KR) 10-2024-0136902

(51) Int. Cl. H01P 5/02; H03F 3/45

(52) U.S. Cl. CPC H01P 5/02; H03F 3/45475

(57) ABSTRACT

A coupler includes a plurality of unit circuits connected to a plurality of differential line pairs and a single-ended line; and a plurality of isolation resistors connected between the plurality of differential line pairs, wherein each unit circuit of the plurality of unit circuits includes: a transformer including a primary side connected to one differential line pair among the plurality of differential line pairs, and a secondary side connected to the single-ended line, and a secondary-side capacitor connected in parallel to the secondary side.

### CROSS-REFERENCE TO RELATED APPLICATIONS

This application claims priority under 35 U.S.C. § 119 to Korean Patent Application No. 10-2024-0136902 filed on Oct. 8, 2024, in the Korean Intellectual Property Office, the disclosure of which is incorporated by reference herein in its entirety.

### BACKGROUND

The present disclosure relates to an N-WAY coupler and a chip including the same.

As 5^{th} generation (5G) new radio (NR) communication becomes commercialized, development of radio frequency integrated-chip (RFIC) used for the communication of a millimeter wave band such as FR2 (frequency range 2) is in progress. In a high-frequency band such as a millimeter wave, the supply voltage also decreases as the performance of a transistor deteriorates due to factors such as parasitic components, and a complementary metal oxide semiconductor (CMOS) process used in an RFIC design is scaled down. Deterioration of transistor performance and reduction of supply voltage soon lead to a decrease in the output power of a power amplifier.

### SUMMARY

Embodiments of the present disclosure provide an N-WAY coupler and a chip including the same.

According to an aspect of an embodiment, a coupler includes: a plurality of unit circuits connected to a plurality of differential line pairs and a single-ended line; and a plurality of isolation resistors connected between the plurality of differential line pairs, wherein each unit circuit of the plurality of unit circuits includes: a transformer including a primary side connected to one differential line pair among the plurality of differential line pairs, and a secondary side connected to the single-ended line, and a secondary-side capacitor connected in parallel to the secondary side.

According to an aspect of an embodiment, a chip includes: a plurality of amplifiers configured to output a plurality of amplification signals through a plurality of differential line pairs; and a coupler connected to the plurality of differential line pairs and configured to combine the plurality of amplification signals and to output a combined signal through a single-ended line, wherein the coupler includes a plurality of unit circuits connected to the plurality of differential line pairs and the single-ended line, and a plurality of isolation resistors connected between the plurality of unit circuits and the plurality of differential line pairs, and each unit circuit of the plurality of unit circuits includes: a transformer including a primary side connected to one differential line pair among the plurality of differential line pairs, and a secondary side is connected to the single-ended line, and a secondary-side capacitor connected in parallel to the secondary side.

According to an aspect of an embodiment, a chip includes: a coupler connected between a plurality of differential line pairs and a single-ended line, and configured to distribute one signal applied through the single-ended line into a plurality of signals; and a plurality of amplifiers connected to the plurality of differential line pairs and configured to amplify the plurality of signals, wherein the coupler includes a plurality of unit circuits connected to the plurality of differential line pairs and the single-ended line, and a plurality of isolation resistors connected between the plurality of unit circuits and the plurality of differential line pairs, and each of the plurality of unit circuits includes: a transformer including a primary side is connected to one differential line pair among the plurality of differential line pairs and a secondary side is connected to the single-ended line, and a secondary-side capacitor connected in parallel to the secondary side.

### BRIEF DESCRIPTION OF THE FIGURES

The above and other objects and features of the present disclosure will become apparent by describing in detail embodiments thereof with reference to the accompanying drawings.

FIG. 1 illustrates a chip, according to some embodiments.

FIGS. 2 to 6 are circuit diagrams illustrating a conversion process of a unit circuit, according to some embodiments.

FIG. 7 is a circuit diagram of a unit circuit converted according to FIGS. 2 to 6.

FIG. 8 is a circuit diagram of a unit circuit, according to some embodiments.

FIG. 9 is a circuit diagram of an N-way coupler, according to some embodiments.

FIG. 10 is a circuit diagram of an N-way chip, according to some embodiments.

FIG. 11 is a circuit diagram of a 2-way coupler, according to some embodiments.

FIG. 12 is a circuit diagram of a 2-way chip, according to some embodiments.

FIG. 13 is a circuit diagram of an N-way chip, according to some embodiments.

FIG. 14 is a circuit diagram of an N-way chip, according to some embodiments.

FIGS. 15 to 18 illustrate simulation waveforms for a coupler, according to some embodiments.

FIG. 19 illustrates an array of transformers included in a coupler, according to some embodiments.

FIG. 20 illustrates a wireless communication device, according to some embodiments.

### DETAILED DESCRIPTION

Hereinafter, embodiments of the present disclosure may be described in detail and clearly to such an extent that an ordinary one in the art easily implements the present disclosure.

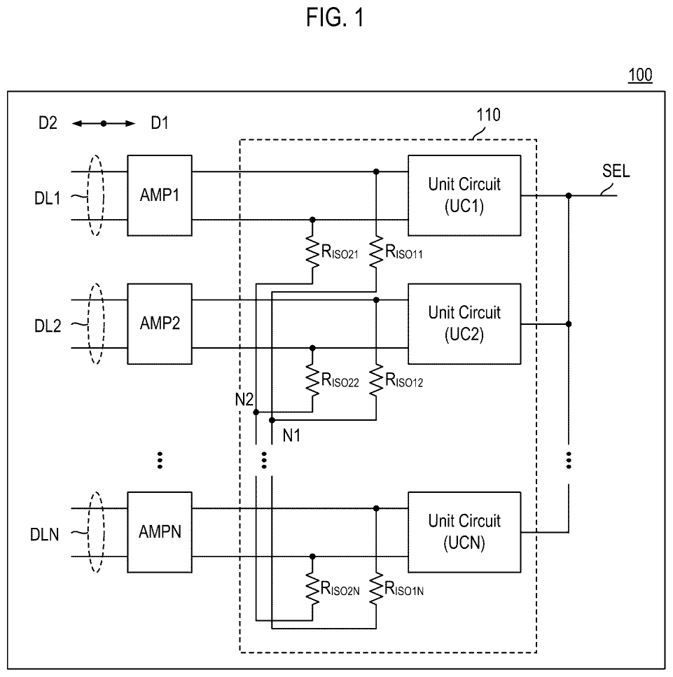

FIG. 1 illustrates a chip, according to some embodiments.

Referring to FIG. 1, a chip 100 according to some embodiments may include a plurality of amplifiers AMP1 to AMPN and a coupler 110.

The plurality of amplifiers AMP1 to AMPN may be configured to output a plurality of amplification signals through a plurality of differential line pairs DL1, DL2, . . . , DLN. In detail, each amplifier may be connected to each differential line pair and may output an amplification signal by amplifying a signal applied to the differential line pair. Accordingly, the amplification signal output through the differential line pair is a differential signal. The plurality of amplifiers AMP1 to AMPN are connected to the coupler 110 through the plurality of differential line pairs DL1 to DLN. That is, a plurality of amplification signals are applied to the coupler 110 through the plurality of differential line pairs DL1 to DLN.

In some embodiments, the plurality of amplifiers AMP1 to AMPN may amplify signals applied to differential line pairs and may output the amplified signals in a first direction D1 being a direction of a single-ended line SEL. For example, each of the plurality of amplifiers AMP1 to AMPN may be a power amplifier.

Alternatively, in some embodiments, the plurality of amplifiers AMP1 to AMPN may amplify signals applied to differential line pairs via the single-ended line SEL and a plurality of unit circuits UC1, UC2, . . . , UCN, and may output the amplified signals in a second direction D2. For example, each of the plurality of amplifiers AMP1 to AMPN may be a low noise amplifier (LNA).

In some embodiments, the number of differential line pairs DL1 to DLN may be composed of N (where N is a natural number greater than or equal to 2). Likewise, the number of amplifiers AMP1 to AMPN may also be configured as N so as to correspond to the number of differential line pairs DL1 to DLN.

The coupler 110 is connected between the single-ended line SEL and the plurality of differential line pairs DL1 to DLN.

In some embodiments, the coupler 110 may be configured to couple a plurality of amplification signals amplified from the plurality of amplifiers AMP1 to AMPN and to output the combined signal to the single-ended line SEL. In this case, the coupler 110 of FIG. 1 may be defined as a combiner. When the number of amplifiers AMP1 to AMPN is N, the coupler 110 may operate as an N-way coupler 110 that combines N amplification signals.

Alternatively, the coupler 110 may be configured to distribute the signal applied through the single-ended line SEL into a plurality of signals (e.g., N signals) through the plurality of unit circuits UC1 to UCN, and to output the N signals to the plurality of amplifiers AMP1 to AMPN. In this case, the coupler 110 of FIG. 1 may be defined as a divider. When the number of amplifiers AMP1 to AMPN is N, the coupler 110 may operate as an N-way divider that divides one signal into N signals. In this case, the plurality of amplifiers AMP1 to AMPN may amplify the plurality of distributed signals.

In some embodiments, the coupler 110 may include the plurality of unit circuits UC1 to UCN and a plurality of isolation resistors R_{ISO11} to R_{ISO1N} and R_{ISO21} to R_{ISO2N}.

The number of unit circuits UC1 to UCN is N, which is the number of differential line pairs DL1 to DLN or the number of amplifiers AMP1 to AMPN.

A differential line pair is connected to one side of each of the plurality of unit circuits UC1 to UCN, and the single-ended line SEL is connected to the other side thereof. Here, the one side may correspond to an output terminal of each of the plurality of amplifiers AMP1 to AMPN. Moreover, in the present application, the differential line pair may correspond to a differential port, and the single-ended line SEL may correspond to a single-ended port.

In some embodiments, each of the plurality of unit circuits UC1 to UCN may be configured to operate as a differential-single-ended transmission line having characteristic impedance having a first value (or magnitude) and a phase having a second value (or magnitude). In the present disclosure, the differential-single-ended transmission line may be defined as a transmission line in which one end is connected to a differential line pair and the other end is connected to the single-ended line SEL.

In some embodiments, each of the plurality of unit circuits UC1 to UCN may be configured to provide signal conversion and impedance matching between the differential line pair and the single-ended line SEL. In detail, the differential-single-ended transmission line equivalently defined as each of the plurality of unit circuits UC1 to UCN has differential characteristic impedance being characteristic impedance defined in the differential line pair, and a single-ended characteristic impedance being characteristic impedance defined in the single-ended line SEL. The differential characteristic impedance or the single-ended characteristic impedance may have a value that allows each of the plurality of unit circuits UC1 to UCN to provide impedance matching between the differential line pair and the single-ended line SEL.

When impedance matching is provided through each of the plurality of unit circuits UC1 to UCN, the impedance (or, the load impedance of the amplifier) defined at the output terminal of each of the plurality of amplifiers AMP1 to AMPN may correspond to reference impedance. Here, the reference impedance may be defined as impedance that allows output power on a load side according to the amplification of each of the plurality of amplifiers AMP1 to AMPN to have the maximum value. In other words, the output power may have the maximum value through impedance matching.

Moreover, a signal (e.g., output signals of the plurality of amplifiers AMP1 to AMPN) transmitted through the plurality of differential line pairs DL1 to DLN and a signal transmitted through the single-ended line SEL may be converted into each other through the plurality of unit circuits UC1 to UCN.

In some embodiments, the second value of the differential-single-ended transmission line equivalent to each of the plurality of unit circuits UC1 to UCN may be 90 degrees. That is, each of the plurality of unit circuits UC1 to UCN may be configured to be equivalent to a differential-single-ended transmission line having a length of λ/4 (where ‘λ’ is the wavelength of the signal).

The plurality of isolation resistors R_{ISO11} to R_{ISO1N} and R_{ISO21} to R_{ISO2N} may be connected between the plurality of differential line pairs DL1 to DLN, and may provide isolation between the differential line pairs (and signals transmitted through the differential line pair).

In some embodiments, the plurality of isolation resistors R_{ISO11} to R_{ISO1N} and R_{ISO21} to R_{ISO2N} may include the plurality of first isolation resistors R_{ISO11} to R_{ISO1N} and the plurality of second isolation resistors R_{ISO21} to R_{ISO2N}. The plurality of first isolation resistors R_{ISO11} to R_{ISO1N} are connected to a first differential line in one differential line pair, and the plurality of second isolation resistors R_{ISO21} to R_{ISO2N} are connected to a second differential line in the one differential line pair. In detail, one end of each of the plurality of first isolation resistors R_{ISO11} to R_{ISO1N} is connected to the first differential line, and the other end thereof is connected to a first node N1. Furthermore, one end of each of the plurality of second isolation resistors R_{ISO21} to R_{ISO2N} is connected to the second differential line, and the other end thereof is connected to a second node N2.

Here, the first differential line may be referred to as a positive line, a differential signal line, a high signal line, or the like, and the second differential line may be referred to as a negative line, an inverted differential signal line, a low signal line, or the like.

In some embodiments, when N is greater than 2, the plurality of first isolation resistors R_{ISO11} to R_{ISO1N} may include N first isolation resistors, and the plurality of second isolation resistors R_{ISO21} to R_{ISO2N} may include N second isolation resistors. Alternatively, when N is 2, one first isolation resistor and one second isolation resistor may be included in the coupler 110. The plurality of isolation resistors R_{ISO11} to R_{ISO1N} and R_{ISO21} to R_{ISO2N} provide isolation between differential lines (or signals passing through differential lines).

The chip 100 according to some embodiments described above may provide high output power by coupling amplification signals through the coupler 110 including the plurality of unit circuits UC1 to UCN and a plurality of isolation resistors R_{ISO11} to R_{ISO1N} and R_{ISO21} to R_{ISO2N}, may provide isolation between the amplification signals, and may provide signal conversion and impedance matching between differential and single-ended lines.

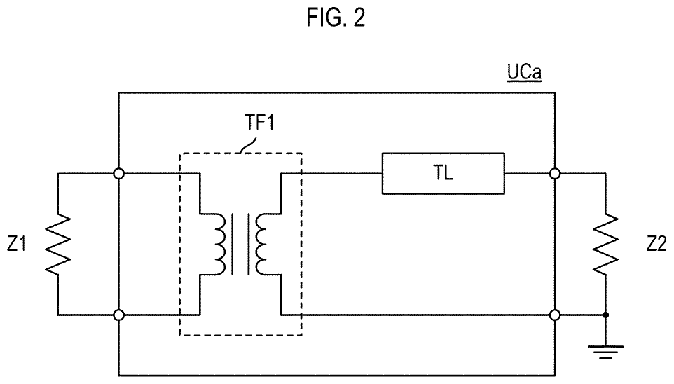

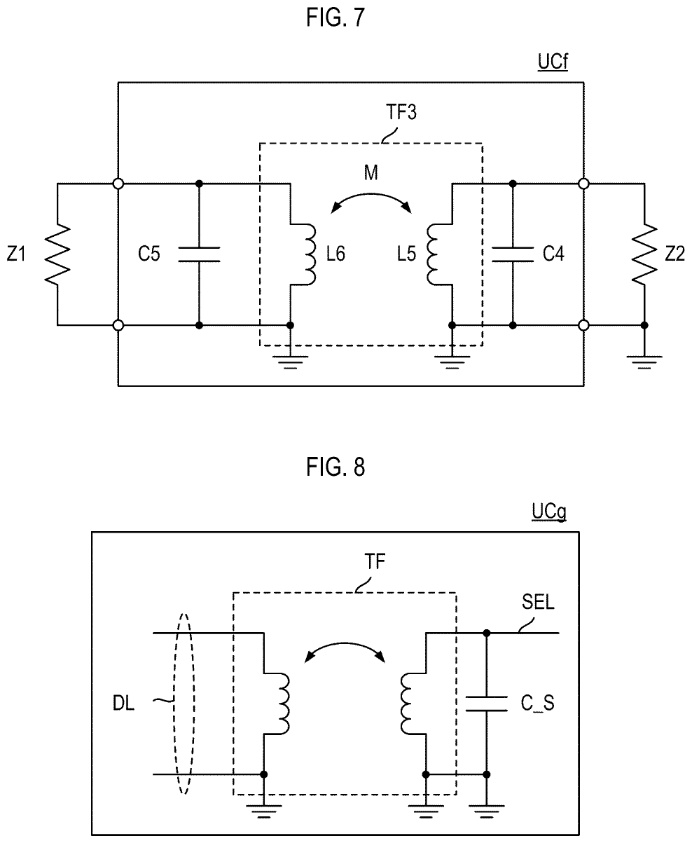

FIGS. 2 to 6 are circuit diagrams illustrating a conversion process of a unit circuit, according to some embodiments. FIG. 7 is a circuit diagram of a unit circuit converted according to FIGS. 2 to 6.

First, referring to FIG. 2, a unit circuit UCa may include a first transformer TF1 and a transmission line TL. The impedances connected to each side of the first transformer TF1 are targets of impedance conversion (or matching). Pieces of impedance of opposite ends of a primary side of the first transformer TF1 are defined as first impedance Z1, and the transmission line TL is connected to a secondary side of the first transformer TF1. In addition, the impedance of both ends of the secondary side of the first transformer TF1 is defined as second impedance Z2, and the transmission line TL is connected in series with the second impedance Z2. Also, one end of the secondary side of the first transformer TF1 is grounded. Accordingly, a signal on the primary side of the first transformer TF1 is a differential signal, and a signal on the secondary side is a single-ended signal.

The first transformer TF1 may be configured as the ‘kind of a matching network for providing conversion between the first impedance Z1 and the second impedance Z2. The turn ratio of the first transformer TF1 may be set according to the relationship between the first impedance Z1 and the second impedance Z2. In some embodiments, when the first impedance Z1 is 2*Z2, the turn ratio of the first transformer TF1 may be set to \sqrt{2}:1. Alternatively, when the first impedance Z1 is k*Z2 (where k is a non-zero positive real number), the turn ratio of the first transformer TF1 may be set to \sqrt{k}:1

For example, when the turn ratio of the first transformer TF1 is 2:1, the unit circuit may match impedance (i.e., the first impedance Z1), which is viewed from the primary side of the first transformer TF1, to four times the second impedance Z2.

The transmission line TL may be configured to have characteristic impedance and a phase difference according to a length. In some embodiments, the transmission line TL may be configured to have specific characteristic impedance and to have a phase difference of 90 degrees. For example, the transmission line TL may have a length of λ/4. The characteristic impedance of the transmission line TL may have various values depending on the number of amplifiers coupled to a unit circuit.

Through the unit circuit UCa, the differential signal and the single-ended signal may be converted to each other, and the first impedance Z1 and the second impedance Z2 may be converted to each other.

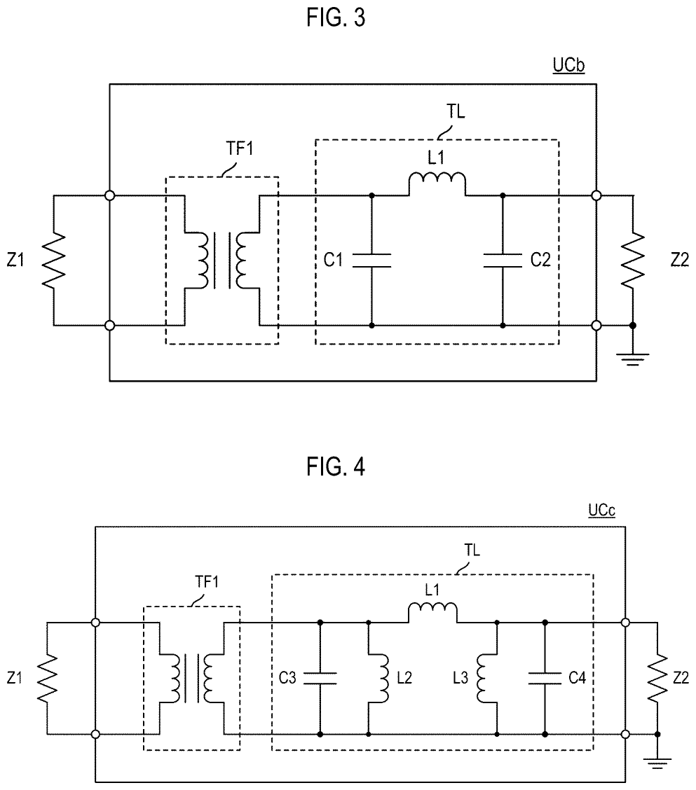

In a unit circuit UCb of FIG. 3, the transmission line TL of FIG. 2 may be equivalently converted into a C-L-C circuit (e.g., a low pass filter). The C-L-C circuit may include a first inductor L1, a first capacitor C1, and a second capacitor C2, which are implemented in a pi shape at opposite ends of the secondary side of the first transformer TF1. In this case, the inductance L_{Q} of each of the first inductor L1 may be set to Z_{C}/ω and the capacitance C_{Q} of each of the first capacitor C1 and the second capacitor C2 may be set to 1/(ωZ_{C}). Here, ω is the angular velocity of a signal.

In a unit circuit UCc of FIG. 4, the first capacitor C1 included in the C-L-C circuit of FIG. 3 may be implemented with a third capacitor C3 and a second inductor L2 that are equivalently connected in parallel with each other, and the second capacitor C2 may be implemented with a fourth capacitor C4 and a third inductor L3 that are equivalently connected in parallel with each other. In this case, when the capacitance of each of the third capacitor C3 and the fourth capacitor C4 is C_{P} and the inductance of each of the second inductor L2 and the third inductor L3 is L_{P}, C_{Q}=C_{P}−1/(ω²L_{P}) may be established.

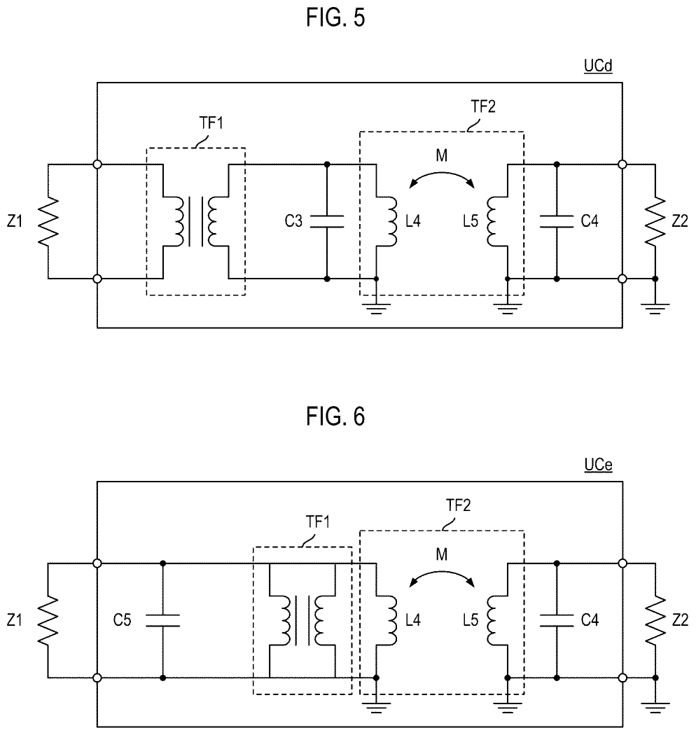

In a unit circuit UCd of FIG. 5, the first inductor L1, the second inductor L2, and the third inductor L3 implemented in a pi shape in FIG. 4 may be equivalently implemented as a second transformer TF2 having a turn ratio of 1:1. The second transformer TF2 includes a fourth inductor L4 placed on the primary side and a fifth inductor L5 placed on the secondary side. In the case, the inductance of each of the fourth inductor LA and the fifth inductor L5 is L_{X}. The inductance L_{X} may have the relationship of

$${L}_{Q} = {L}_{X}^{2} / M - M$$

with inductance L_{Q}. In the case, ‘M’ is the mutual inductance of the second transformer TF2. Furthermore, the inductance L_{X} may have the relationship of L_{P}=L_{X}+M with the inductance L_{P}.

In a unit circuit UCe of FIG. 6, when being passed to the primary side of the first transformer TF1, the third capacitor C3 connected in parallel to the fourth inductor LA of FIG. 5 may be implemented as a fifth capacitor C5. In this case, the fifth capacitor C5 may have a capacitance that is (1/k) times the capacitance of the fourth capacitor C4. For example, when k is 2, the capacitance of the fifth capacitor C5 is C_{P}/2.

In a unit circuit UCf of FIG. 7, the first transformer TF1 and the second transformer TF2 of FIG. 6 may be implemented with a third transformer TF3 equivalent thereto. The third transformer TF3 may include a sixth inductor L6 placed on the primary side and the fifth inductor L5 placed on the secondary side. In this case, the inductance of the sixth inductor L6 may have the inductance that is ‘k’ times the inductance L_{X} of the fifth inductor L5. For example, when k is 2, the inductance of the sixth inductor L6 is 2L_{X}.

As described above, the unit circuits of FIGS. 2 to 7 are equivalent to each other. In other words, through the unit circuit UCf of FIG. 7, a transformer for impedance matching of FIG. 2 and the transmission line TL having specific characteristic impedance and a phase difference may be implemented. In the unit circuit UCf of FIG. 7, the transformer and the transmission line TL is equivalently implemented as one transformer and a capacitor connected to each transformer. Accordingly, the unit circuit UCf of FIG. 7 may provide impedance matching between the impedance of one end of the transmission line TL and the impedance of the other end thereof, similarly to the first transformer TF1 of FIG. 2, while reducing power loss and area due to a multi-stage structure (a transformer and the transmission line TL). Moreover, the unit circuit UCf of FIG. 7 may operate as a differential-single-ended transmission line TL that is capable of converting a differential signal of one end of the transmission line TL and a single-ended signal of the other end thereof while reducing power loss and area.

FIG. 8 is a circuit diagram of a unit circuit, according to some embodiments.

Referring to FIG. 8, according to some embodiments, a unit circuit UCg may be configured while the fifth capacitor from the unit circuit of FIG. 7 is omitted. In detail, the unit circuit UCg may include a transformer TF and a secondary-side capacitor C_S.

A primary side of the transformer TF is connected to a differential line pair (DL) and a secondary side thereof connected to the single-ended line SEL. The transformer TF may have a turn ratio of k:1. For example, the turn ratio may be 2:1.

The secondary-side capacitor C_S is connected in parallel to the secondary side of the transformer TF. When a capacitor is additionally connected to the primary side (i.e., the differential line pair DL) of the transformer TF, the unit circuit may operate as a differential-single-ended transmission line capable of providing impedance matching.

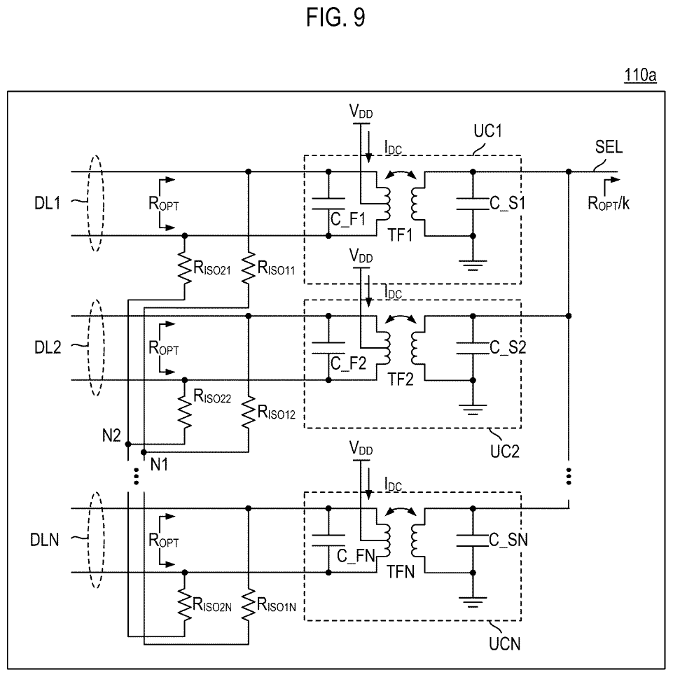

FIG. 9 is a circuit diagram of an N-way coupler, according to some embodiments.

Referring to FIG. 9, in some embodiments, a coupler 110a may include the plurality of unit circuits UC1 to UCN and the plurality of isolation resistors R_{ISO11} to R_{ISO1N} and R_{ISO21} to R_{ISO2N}.

The plurality of unit circuits UC1 to UCN may be connected between N differential line pairs DL1 to DLN and the single-ended line SEL, and may be configured according to the above-described embodiments (e.g., FIGS. 2 to 8). That is, each unit circuit may include a transformer, of which the primary side is connected to one differential line pair among the plurality of differential line pairs DL1 to DLN and of which the secondary side is connected to the single-ended line SEL, and the secondary-side capacitor C_S connected in parallel to the secondary side.

In some embodiments, each of the plurality of unit circuits UC1 to UCN may further include a primary-side capacitor C_F connected in parallel to the primary side. For example, the primary-side capacitor C_F may have capacitance that is (1/k) times the capacitance of the secondary-side capacitor C_S. The primary-side capacitor C_F may be omitted.

According to the embodiments described above, the plurality of unit circuits UC1 to UCN are configured equivalently to the unit circuit of FIG. 2, and thus impedance matching and signal conversion between differential and single-ended lines may be provided with less power loss and area.

As each unit circuit is equivalently configured to include the first transformer of FIG. 2, matching for the differential characteristic impedance being the impedance defined in a differential line pair may be provided. For example, when k is 2 and the single-ended characteristic impedance defined in the single-ended line SEL is “R_{OPT}/2”, the differential characteristic impedance may be matched to R_{OPT}. Here, R_{OPT} may correspond to the above-described reference impedance.

In some embodiments, each transformer may be configured such that a bias current flows in a center tap. The bias current may be generated through a supply voltage V_{DD} connected to the center tap of each transformer and may be provided to a transistor included in an amplifier capable of being connected to the coupler 110a. In this case, the center tap of each transformer is grounded with respect to alternating current (AC), and thus the bias current may be supplied without an RF choke for AC ground. In detail, because each transformer is connected in parallel to each differential line pair, differential signals flowing through each differential line pair are combined at the center tap of each transformer. Accordingly, the center tap may be grounded with respect to the AC.

The plurality of isolation resistors R_{ISO11} to R_{ISO1N} and R_{ISO21} to R_{ISO2N} may be connected between the plurality of differential line pairs DL1 to DLN, and may provide isolation between differential line pairs (and signals transmitted through the differential line pair) connected to the coupler 110a. The plurality of first isolation resistors R_{ISO11} to R_{ISO1N} are connected to the first node N1 and a first differential line in one differential line pair, and the plurality of second isolation resistors R_{ISO21} to R_{ISO2N} are connected to the second node N2 and a second differential line in the one differential line pair.

According to some embodiments, the plurality of isolation resistors R_{ISO11} to R_{ISO1N} and R_{ISO21} to R_{ISO2N} may be configured such that respective impedance has the same magnitude (e.g., R_{OPT}) as the differential characteristic impedance.

The coupler 110a may have the plurality of unit circuits UC1 to UCN equivalently including transmission lines and the plurality of isolation resistors R_{ISO11} to R_{ISO1N} and R_{ISO21} to R_{ISO2N}, and thus it may have the characteristics of a Wilkinson coupler as it is. Accordingly, the coupler 110a may provide high isolation between a plurality of differential port pairs and may maintain the matched impedance (e.g., differential characteristic impedance is R_{OPT}, and single-ended characteristic impedance is R_{OPT}/k) in a wide bandwidth. Moreover, as described above, the coupler 110a may provide signal conversion and impedance matching between the differential line pair and the single-ended line SEL. Furthermore, the coupler 110a may be implemented with only transformers and capacitors instead of matching networks and transmission lines, thereby reducing power loss and area.

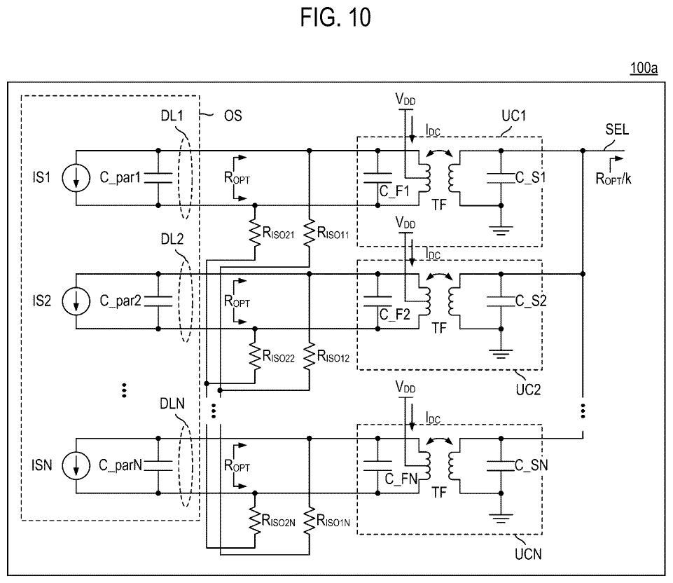

FIG. 10 is a circuit diagram of an N-way chip, according to some embodiments.

Referring to FIG. 10, a chip 100a according to some embodiments may include a coupler including the plurality of unit circuits UC1 to UCN, which are connected to the plurality of differential line pairs DL1 to DLN and the single-ended line SEL and combining amplification signals, the plurality of isolation resistors R_{ISO11} to R_{ISO1N} and R_{ISO21} to R_{ISO2N} connected between the plurality of differential line pairs DL1 to DLN, and an output terminal circuit OS connected to the plurality of differential line pairs DL1 to DLN.

The output terminal circuit OS includes a plurality of current sources IS1 to ISN, which correspond to output terminals of amplifiers and are connected to differential line pairs, respectively. The plurality of current sources IS1 to ISN may be voltage control current sources, and may equivalently correspond to transistors included in the output terminal of one of a plurality of amplifiers. A capacitor connected in parallel to each current source is a parasitic capacitance. Pieces of parasitic capacitance C_par1 to C_parN may perform the role of the primary-side capacitor C_F according to the above-described embodiments in each unit circuit together, or may replace the primary-side capacitor C_F.

According to some embodiments, the primary-side capacitor C_F may be omitted when the capacitance of each of the plurality of parasitic capacitance components C_par1 to C_parN is (1/k) times the capacitance of the secondary-side capacitor C_S. For example, when the parasitic capacitance is half the capacitance of the secondary-side capacitor C_S when k is 2, the primary-side capacitor C_F may be omitted.

Alternatively, when the primary-side capacitor C_F is configured according to some embodiments, the secondary-side capacitor C_S may be configured to have a capacitance that is k times the sum of the capacitance of the primary-side capacitor C_F and the parasitic capacitance of one of a plurality of amplifiers. For example, when k is 2, the capacitance of the secondary-side capacitor C_S is twice the sum of the parasitic capacitance and the capacitance of the primary-side capacitor C_F.

The transformer included in each unit circuit, the secondary-side capacitor C_S (or, additionally, the primary-side capacitor C_F)), and the parasitic capacitance, which are included in the chip 100a according to the above-described embodiments, may operate equivalently to a transmission line of 90 degrees having differential characteristic impedance of \sqrt{N}R_{OPT} and a single-ended characteristic impedance of (1/k)*\sqrt{N}R_{OPT}, and a transformer for impedance matching. For example, when k is 2, the single-ended characteristic impedance is 0.5*\sqrt{N}R_{OPT}. That is, each unit circuit and the parasitic capacitance may be equivalent to the transmission line of a Wilkinson coupler. Accordingly, the chip 100a may provide high isolation between a plurality of differential port pairs and may maintain matched impedance in a wide bandwidth.

In some embodiments, the bias current may be configured to flow to each current source included in the output terminal circuit OS through the supply voltage V_{DD} connected to the center tap of each transformer.

While having low power loss and area, the chip 100a according to the above-described embodiments may couple amplification signals with the characteristics of a Wilkinson coupler. Moreover, the chip 100a does not require an additional inductor for resonance of the parasitic capacitance by using the parasitic capacitance and a transformer as the transmission line of the Wilkinson coupler.

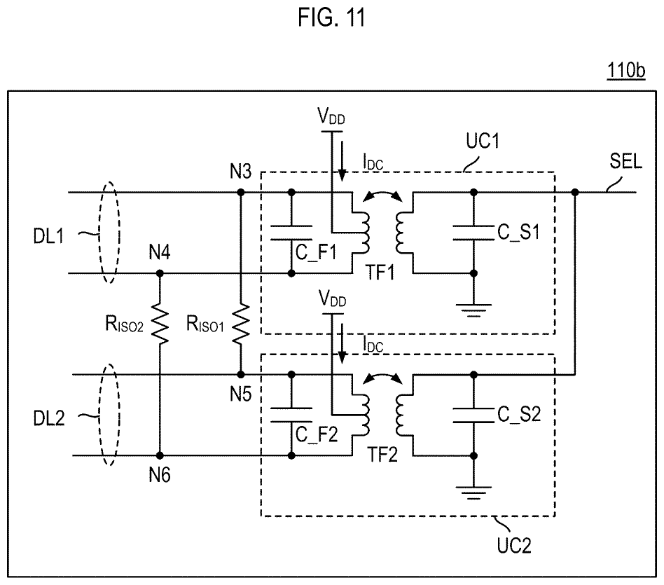

FIG. 11 is a circuit diagram of a 2-way coupler, according to some embodiments.

Referring to FIG. 11, a coupler 110b according to some embodiments may include the first unit circuit UC1 connected to the first differential line pair DL1 and the single-ended line SEL, the second unit circuit UC2 connected to the second differential line pair DL2 and the single-ended line SEL, a first isolation resistor R_{ISO1}, and a second isolation resistor R_{ISO2}. Here, the first isolation resistor R_{ISO1} and the second isolation resistor R_{ISO2} may be connected between the first differential line pair DL1 and the second differential line pair DL2.

The first unit circuit UC1 includes the first transformer TF1, whose primary side is connected to the first differential line pair DL1 and whose secondary side is connected to the single-ended line SEL, and a secondary-side capacitor C_S1 connected in parallel to the secondary side.

The supply voltage V_{DD} for providing a bias current I_{DC} to a transistor capable of being connected to the first differential line pair DL1 may be connected to the center tap of the first transformer TF1. The center tap of the first transformer TF1 is AC-grounded, and thus the bias current may be provided without affecting an AC operation.

In some embodiments, the first unit circuit UC1 may further include a primary-side capacitor C_F1 connected in parallel to the primary side.

The second unit circuit UC2 includes the second transformer TF2, whose primary side is connected to the second differential line pair DL2 and whose secondary side is connected to the single-ended line SEL, and a secondary-side capacitor C_S2 connected in parallel to the secondary side.

The supply voltage V_{DD} for providing a bias current I_{DC} to a transistor capable of being connected to the second differential line pair DL2 may be connected to the center tap of the second transformer TF2. The center tap of the second transformer TF2 is AC-grounded, and thus the bias current may be provided without affecting an AC operation.

In some embodiments, the second unit circuit UC2 may further include a primary-side capacitor C_F2 connected in parallel to the primary side.

According to the embodiments described above, the first unit circuit UC1 and the second unit circuit UC2 may provide signal conversion and impedance matching between the differential line pair and the single-ended line SEL.

The first isolation resistor is connected to a third node N3 connected to the first differential line pair DL1, and a fifth node N5 connected to the second differential line pair DL2. The second isolation resistor is connected to a fourth node N4 connected to the second differential line pair DL2, and a sixth node N6 connected to the second differential line pair DL2. Each isolation resistor provides isolation between differential lines of a differential line pair.

The coupler 110b according to the above-described embodiments may provide the characteristics of a Wilkinson coupler with low power loss and area. Moreover, the coupler 110b may provide signal conversion and impedance matching between the differential line pair and the single-ended line SEL.

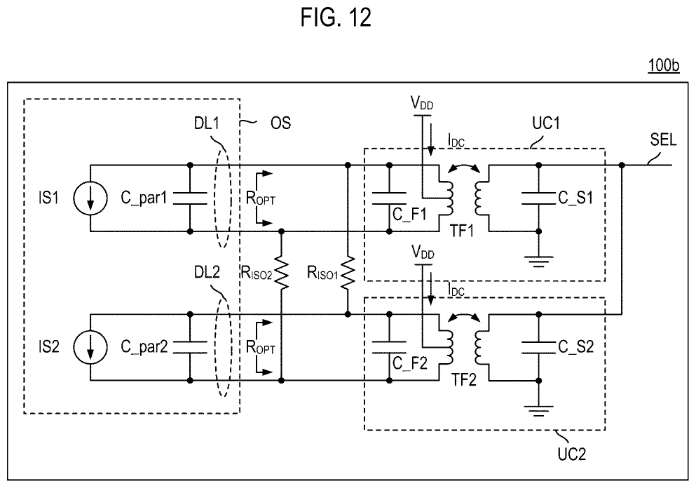

FIG. 12 is a circuit diagram of a 2-way chip, according to some embodiments.

Referring to FIG. 12, a chip 100b according to some embodiments may include a coupler including the first unit circuit UC1, the second unit circuit UC2, a first isolation resistor, and a second isolation resistor for coupling amplification signals, and an output terminal circuit connected to the first differential line pair DL1 and the second differential line pair DL2.

The output terminal circuit includes a first current source IS connected to the first differential line pair DL1, and a second current source IS2 connected to the second differential line pair DL2. Pieces of parasitic capacitance C_par1 and C_par2 connected in parallel to each current source may perform the role of the primary-side capacitor C_F according to the above-described embodiments in each unit circuit together, or may replace the primary-side capacitor C_F.

According to the embodiments described above, the primary-side capacitor C_F may be omitted depending on the magnitude of the capacitance of each of parasitic capacitance components C_par1 and C_par2.

The first isolation resistor and the second isolation resistor provide isolation between differential line pairs. In some embodiments, respective impedance may be configured to have the same magnitude (e.g., R_{OPT}) as the differential characteristic impedance.

The first transformer TF1, a first capacitor C_F1, and a second capacitor C_S1 of the first unit circuit UC1 may equivalently operate as a 90-degree transmission line having differential characteristic impedance of \sqrt{2}Rₒₚₜ and a single-ended characteristic impedance of \sqrt{2}/2Rₒₚₜ and a transformer for impedance matching.

Likewise, the second transformer TF2, a first capacitor C_F2, and a second capacitor C_S2 of the second unit circuit UC2 may equivalently operate as a 90-degree transmission line having differential characteristic impedance of \sqrt{2}Rₒₚₜ and a single-ended characteristic impedance of \sqrt{2}/2Rₒₚₜ and a transformer for impedance matching.

In some embodiments, the bias current may be configured to flow to the first current source IS1 through the supply voltage V_{DD} connected to the center tap of the first transformer TF1, and the bias current may be configured to flow to the second current source IS2 through the supply voltage V_{DD} connected to the center tap of the second transformer TF2.

While having low power loss and area, the chip 100b according to the above-described embodiments may couple amplification signals with the characteristics of a Wilkinson coupler. Moreover, the chip 100b does not require an additional inductor for resonance of the parasitic capacitance by using the parasitic capacitance and a transformer as the transmission line of the Wilkinson coupler.

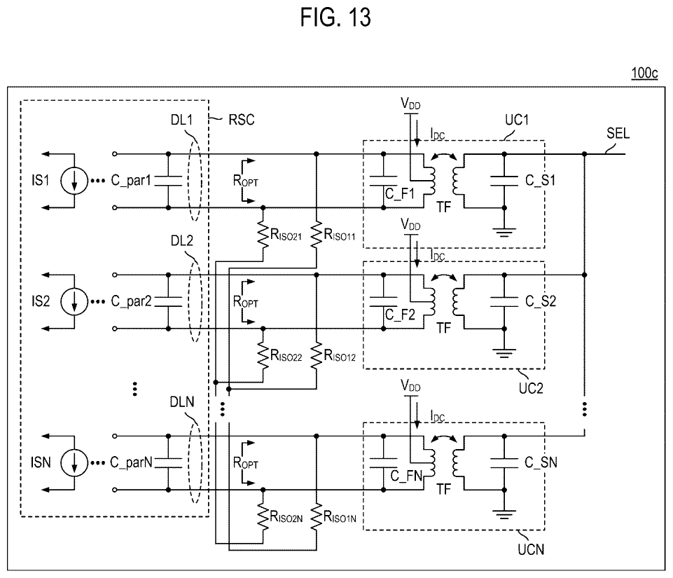

FIG. 13 is a circuit diagram of an N-way chip, according to some embodiments.

Referring to FIG. 13, a chip 100c according to some embodiments may include a coupler including the plurality of unit circuits UC1 to UCN and the plurality of isolation resistors R_{ISO11} to R_{ISO1N} and R_{ISO21} to R_{ISO2N}, and a reception amplification circuit RSC connected to the plurality of differential line pairs DL1 to DLN.

The plurality of unit circuits UC1 to UCN may distribute one signal, which is provided from the single-ended line SEL, into N signals and may provide the N distributed signals to the reception amplification circuit RSC. In this case, one signal being a single-ended signal may be converted into N signals being differential signals through the plurality of unit circuits UC1 to UCN.

The transformer and the secondary-side capacitor C_S (or, additionally, the primary-side capacitor C_F) included in each unit circuit included in the chip 100c according to the above-described embodiments, and parasitic capacitance included in the reception amplification circuit RSC may operate equivalently to a transformer for impedance matching and a transmission line of a Wilkinson coupler. Accordingly, the chip 100c may provide high isolation between a plurality of differential port pairs and may maintain matched impedance in a wide bandwidth.

In some embodiments, the bias current may be configured to flow to each current source included in an output terminal circuit through the supply voltage V_{DD} connected to the center tap of each transformer.

The reception amplification circuit RSC is configured to amplify the N distributed signals and includes the plurality of current sources IS1 to ISN connected to each differential line pair. The plurality of current sources IS1 to ISN may be voltage control current sources, and may equivalently correspond to transistors included in the output terminal of one of a plurality of amplifiers. Pieces of parasitic capacitance C_par1 to C_parN may perform the role of the primary-side capacitor C_F according to the above-described embodiments in each unit circuit together, or may replace the primary-side capacitor C_F.

While having low power loss and area and the characteristics of a Wilkinson coupler, the chip 100c according to the above-described embodiments may distribute a single-ended signal. Moreover, the chip 100c does not require an additional inductor for resonance of the parasitic capacitance by using the parasitic capacitance and a transformer as the transmission line of the Wilkinson coupler.

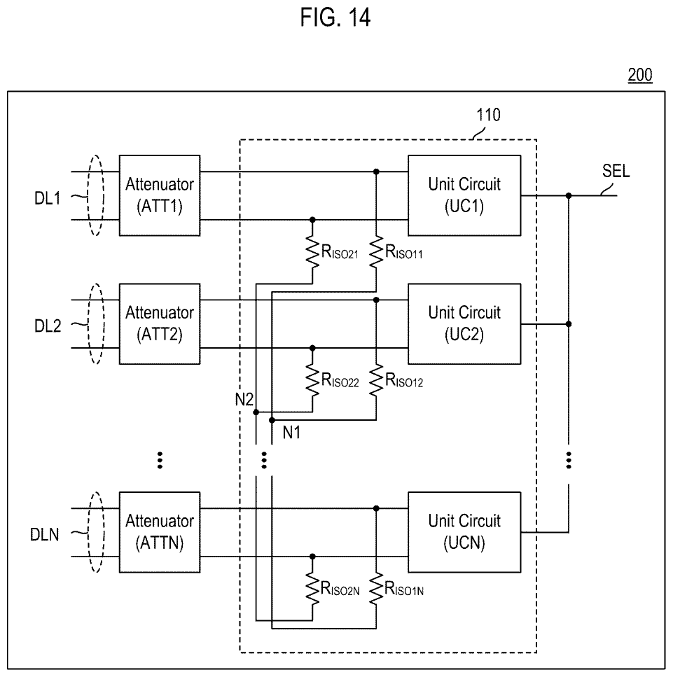

FIG. 14 is a circuit diagram of an N-way chip, according to some embodiments. Hereinafter, detailed descriptions of portions the same as the above-described portions may be omitted.

Referring to FIG. 14, in some embodiments, a chip 200 may further include a plurality of attenuators ATT1 to ATTN connected to the plurality of differential line pairs DL1 to DLN, in addition to the coupler 110 connected between the plurality of differential line pairs DL1 to DLN and the single-ended line SEL.

The plurality of attenuators ATT1 to ATTN may be configured to attenuate the magnitude of a signal transmitted through the plurality of differential line pairs DL1 to DLN. For example, the plurality of attenuators ATT1 to ATTN may include a fixed attenuator with a fixed attenuation amount, a variable attenuator with a variable attenuation amount, and the like. For example, each of the plurality of attenuators ATT1 to ATTN may be implemented as being in T-type, a pi-type, a bridge-T-type, an O-type, and the like including pieces of impedance and/or pieces of variable impedance.

The coupler 110 may provide isolation for attenuated signals through the plurality of isolation resistors R_{ISO11} to R_{ISO1N} and R_{ISO21} to R_{ISO2N} and the plurality of attenuators ATT1 to ATTN. The coupler 110 may combine the attenuated signals through the plurality of unit circuits UC1 to UCN and may output the combined signal to the single-ended line SEL.

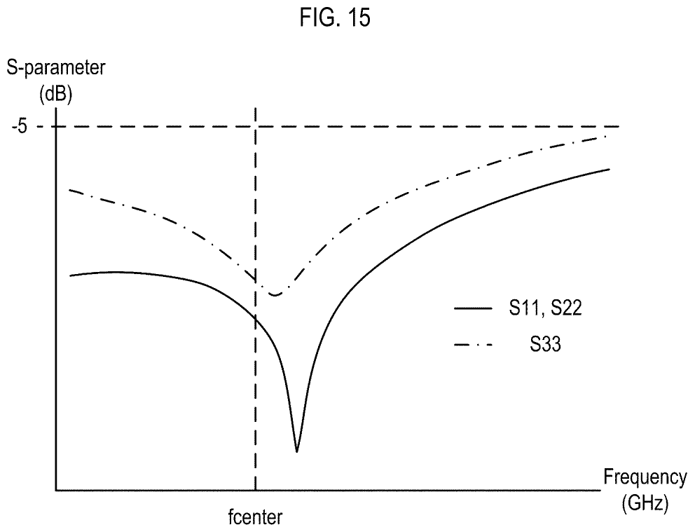

FIGS. 15, 16, 17, and 18 illustrate simulation waveforms for a coupler, according to some embodiments.

Referring to FIG. 15, waveforms or curves for S-parameters S11, S22, and S33 corresponding to return losses for each frequency are shown. It may be seen that the S-parameters indicate maximum values near a center frequency in all ports. That is, it may be seen that the differential characteristic impedance and single-ended characteristic impedance of each port are matched with each other.

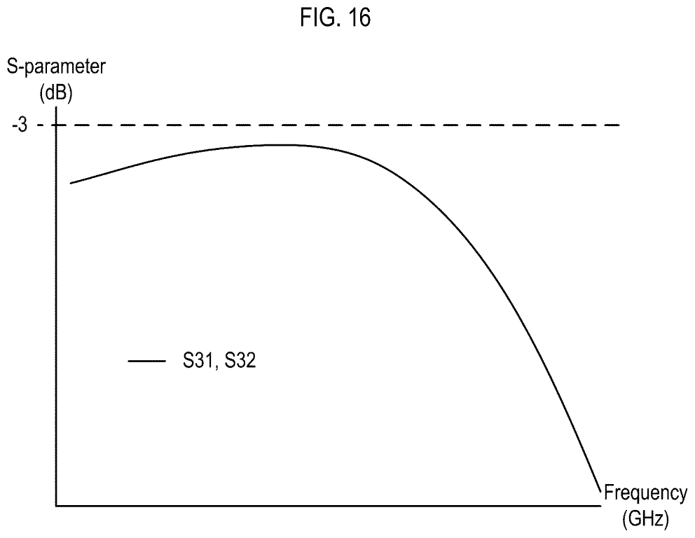

Referring to FIG. 16, waveforms of curves for S31 and S32 for each frequency are shown. It may be seen that high isolation is ensured between ports because S31 and S32 are approximately −3 dB.

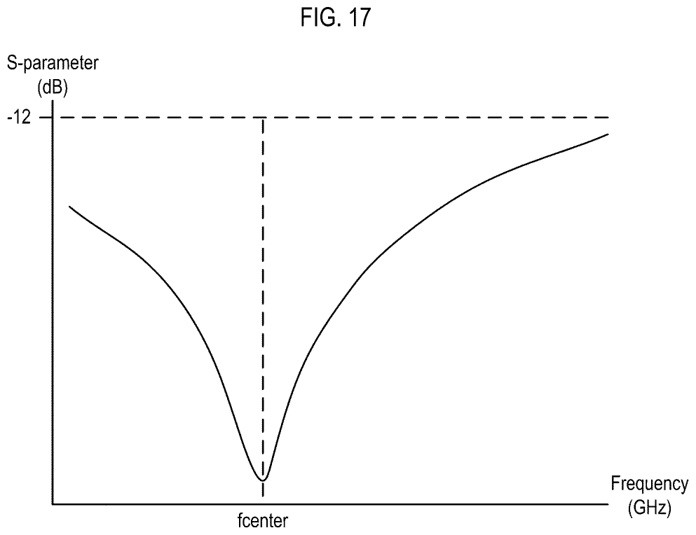

Referring to FIG. 17, a waveform or curve for S21 for each frequency is shown. It may be seen that S21 shows the maximum value near the center frequency. It may be seen that high isolation is ensured between ports.

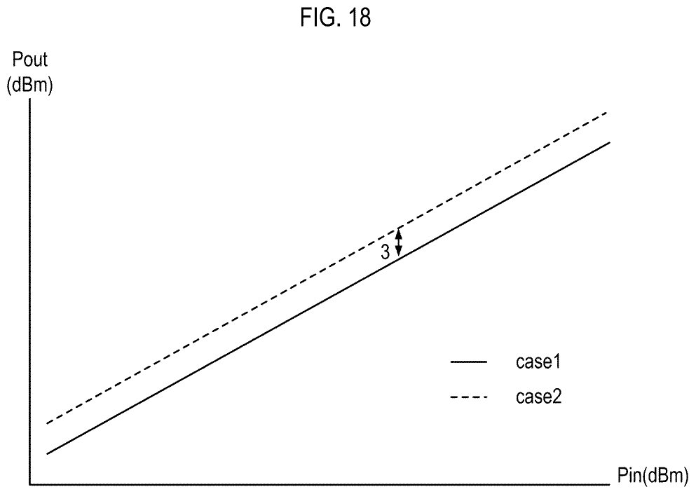

Referring to FIG. 18, it is shown that power is coupled in a single-ended line when the power is input to a 2-way coupler. It may be seen that output power for port 12 increases by about 3 dB when the power is coupled (case 2) due to a 2-way coupler, compared to a case where the power is not coupled (case 1).

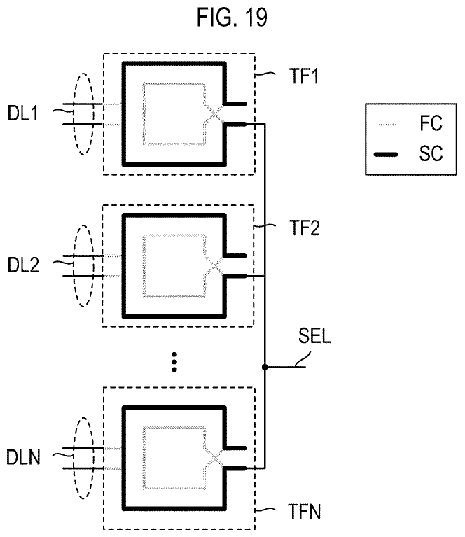

FIG. 19 illustrates an array of transformers included in a coupler, according to some embodiments.

Referring to FIG. 19, in some embodiments, the array of transformers may further include a plurality of transformers TF1 to TFN connected between the plurality of differential line pairs DL1 to DLN and the single-ended line SEL. Each transformer may include a primary side coil FC and a secondary side coil SC.

Each primary side coil FC may be connected to each differential line pair. For example, the primary side coil FC may be configured to have a turn ratio k. In the case of FIG. 19, the turn ratio of the primary side coil FC is 2. The primary side coil FC may form k loops depending on the turn ratio. As shown, when the turn ratio of the primary side coil FC is 2, the primary side coil FC may include an outer loop that overlaps the secondary side coil SC, and an inner loop that does not overlap the outer loop. In this case, the outer loop may be formed in a different layer from that of the secondary side coil SC.

Both ends of the outer loop of the primary side coil FC may be connected to each differential line pair.

Each of the secondary side coils SC may be connected to the single-ended line SEL in common. The secondary side coil SC may be configured to have a turn ratio of 1. The secondary side coil SC may include one loop that overlaps the primary side coil FC and is formed in a different layer.

One end among both ends of the one loop may be connected to the single-ended line SEL, and the other end thereof may be grounded.

The transformer array according to the embodiments described above is included in a coupler. In other words, the coupler may replace the transformer for impedance matching and the transmission line with a single transformer, thereby reducing power loss and area.

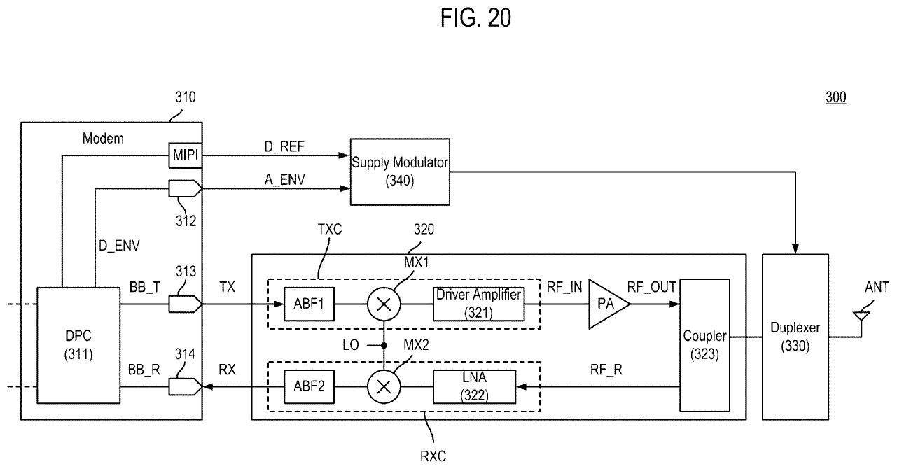

FIG. 20 illustrates a wireless communication device, according to some embodiments.

Referring to FIG. 20, a wireless communication device 300 may include a modem 310, an RF Integrated-Circuit (RFIC) 320, a duplexer 330, a supply modulator 340, and an antenna ANT.

The modem 310 may include a digital processing circuit 311, a first digital-to-analog converter (DAC) 312, a second DAC 313, an analog-to-digital converter (ADC) 314, and a mobile industry processor interface (MIPI). The modem 310 may process a baseband signal BB_T (e.g., including I signal and Q signal) including information to be transmitted through the digital processing circuit 311 in compliance with various communication schemes. The modem 310 may process a received baseband signal BB_R through the digital processing circuit 311 in compliance with the various communication schemes.

For example, the modem 310 may process a signal to be transmitted or a received signal in compliance with a communication scheme such as OFDM (Orthogonal Frequency Division Multiplexing), OFDMA (Orthogonal Frequency Division Multiple access), WCDMA (Wideband Code Multiple Access), or HSPA+ (High Speed Packet Access+). In addition, the modem 310 may process the baseband signal BB_T or BB_R in compliance with various kinds of communication schemes (i.e., various communication schemes to which a technology for modulating or demodulating amplitude and a frequency of the baseband signal BB_T or BB_R is applied).

According to some embodiments, the modem 310 may extract an envelope of the baseband signal BB_T through the digital processing circuit 311 and may generate a digital envelope signal D_ENV based on the extracted envelope.

According to some embodiments, the modem 310 may generate an average power signal D_REF based on an average power tracking (APT) table (i.e., an APT table) stored in a memory. The APT table may store information of a necessary power supply voltage of a power amplifier PA according to an expected output power (or a transmission power) of the antenna ANT and information of the average power signal D_REF corresponding to the necessary power supply voltage of the power amplifier PA. Accordingly, when the expected output power of the antenna ANT is decided, the modem 310 may generate the average power signal D_REF by using the APT table and may provide the generated average power signal D_REF to the supply modulator 340 as a reference voltage signal.

The digital processing circuit 311 may perform various processing operations on a baseband signal in a digital domain.

For example, the digital processing circuit 311 may perform generating an average power signal, extracting an envelope, generating a digital envelope signal, crest factor reduction (CFR), shaping function (SF), digital pre-distortion (DPD), delay correction task, and the like.

The CFR may reduce a peak-to-average power ratio (PAPR) of a communication signal (e.g., the baseband signal BB_T). The SF may modify the digital envelope signal D_ENV such that efficiency and linearity of the power amplifier PA are improved. The DPD may compensate for distortion of the power amplifier PA in a digital domain so as to be linearized. Moreover, the delay correction task may correct the delay of the digital envelope signal D_ENV or the baseband signal BB_T.

The digital processing circuit 311 may output the digital envelope signal D_ENV and the baseband signal BB_T. The digital envelope signal D_ENV may be converted into an analog envelope signal A_ENV through the first DAC 312, and the analog envelope signal A_ENV may be provided to the supply modulator 340; the baseband signal BB_T may be converted into a transmit signal TX through the second DAC 313, and the transmit signal TX may be provided to a transmission circuit TXC.

The digital processing circuit 311 may further include an internal component to process the above operations (i.e., baseband signal processing, envelope extraction, and digital envelope signal generation).

At least one or more second DACs 313 and ADCs 314 may be provided. The modem 310 may generate the transmit signal TX by performing digital-to-analog conversion on the baseband signal BB_T by using the second DAC 313. Also, the modem 310 may be provided with a receive signal RX being an analog signal from the RFIC 320. The modem 310 may perform analog-to-digital conversion on the receive signal RX through the ADC 314 included therein and may extract the baseband signal BB_R being a digital signal. For example, the receive signal RX may be implemented with differential signals including a positive signal and a negative signal.

The RFIC 320 may generate an RF input signal RF_IN by performing frequency up-conversion on the transmit signal TX or may generate the receive signal RX by performing frequency down-conversion on an RF receive signal RF_R. In detail, the RFIC 320 may include a transmission circuit TXC for frequency up-conversion, a reception circuit RXC for frequency down-conversion, a local oscillator LO, the power amplifier PA, and a coupler 323.

Here, the transmission circuit TXC may include a first analog baseband filter ABF1, a first mixer MX1, and a driver amplifier 321. For example, the first analog baseband filter ABF1 may include a low pass filter.

The first analog baseband filter ABF1 may filter the transmit signal TX received from the modem 310 so as to be provided to the first mixer MX1. That is, the first analog baseband filter ABF1 may filter the baseband signal. The first mixer MX1 may perform frequency up-conversion for converting a frequency of the transmit signal TX from a baseband to a high-frequency band through a frequency signal provided by the local oscillator LO. The transmit signal TX may be provided to the driver amplifier 321 as the RF input signal RF_IN through such the frequency up-conversion, and the driver amplifier 321 may primarily amplify the power of the RF input signal RF_IN so as to be provided to the power amplifier PA.

The power amplifier PA may be supplied with a DC voltage or a power supply voltage (i.e., a dynamically variable output voltage), may secondarily amplify the power of the RF input signal RF_IN based on the supplied power supply voltage, and may generate an RF output signal RF_OUT. The power amplifier PA may provide the generated RF output signal RF_OUT thus generated to the duplexer 330 through the coupler 323.

The reception circuit RXC may include a second analog baseband filter ABF2, a second mixer MX2, and a low-noise amplifier (LNA) 322. For example, the second analog baseband filter ABF2 may include a low pass filter.

The LNA 322 may amplify the RF receive signal RF_R provided from the duplexer 330 through the coupler 323 so as to be provided to the second mixer MX2. The second mixer MX2 may perform frequency down-conversion for converting a frequency of the RF receive signal RF_R from a high-frequency band to a baseband through a frequency signal provided by the local oscillator LO. That is, the second mixer MX2 may convert the RF receive signal RF_R into a baseband signal through an LO signal.

The RF receive signal RF_R corresponding to the baseband signal may be provided to the second analog baseband filter ABF2 as the receive signal RX through the above frequency down-conversion, and the second analog baseband filter ABF2 may filter the receive signal RX corresponding to the baseband signal so as to be provided to the modem 310.

The coupler 323 may combine an amplification signal output from the power amplifier PA and may provide the combined signal to the duplexer 330. Alternatively, the coupler 323 may distribute the signal received from the duplexer 330 into a plurality of signals and may provide the plurality of signals to the LNA 322.

The coupler 323 may include a plurality of unit circuits and a plurality of isolation resistors, which is implemented according to the embodiments described above (e.g., FIGS. 1 to 14, FIG. 19) or according to the embodiments described above.

The power amplifier PA and/or the LNA 322 and the coupler 323 may be connected through a plurality of differential line pairs, and the coupler 323 and the duplexer 330 may be connected through a single-ended line. The coupler 323 may provide signal conversion and impedance matching between the differential line pair and the single-ended line.

The coupler 323 may be implemented as N-way depending on the number of power amplifier PAs and/or the number of LNAs 322.

In an embodiment, the wireless communication device 300 may transmit a transmit signal through a plurality of frequency bands by using carrier aggregation (CA). Also, to this end, the wireless communication device 300 may include a plurality of power amplifiers PA for amplifying powers of a plurality of RF input signals RF_IN respectively corresponding to a plurality of carriers. However, in an embodiment of the present disclosure, for convenience of description, the description will be given for one power amplifier PA.

The duplexer 330 may be connected with the antenna ANT and may separate a transmission frequency from a reception frequency. In detail, the duplexer 330 may separate the RF output signal RF_OUT provided from the power amplifier PA for each frequency band so as to be provided to the corresponding antenna ANT. Also, the duplexer 330 may provide an external signal provided from the antenna ANT to the LNA 322 of the reception circuit RXC of the RFIC 320. For example, the duplexer 330 may include a front end module with integrated duplexer (FEMiD).

In an embodiment, the wireless communication device 300 may include a switch structure capable of separating the transmission frequency and the reception frequency instead of the duplexer 330. Also, the wireless communication device 300 may include a structure implemented with the duplexer 330 and a switch for the purpose of separating the transmission frequency and the reception frequency. However, for convenience of description, in an embodiment of the present disclosure, the description will be given as the duplexer 330 capable of separating the transmission frequency and the reception frequency is included in the wireless communication device 300.

The supply modulator 340 may generate a modulated output voltage, the level of which varies dynamically, based on the analog envelope signal A_ENV and the average power signal D_REF and may provide the output voltage as a power supply voltage of the power amplifier PA.

In detail, the supply modulator 340 may be provided with the average power signal D_REF and the analog envelope signal A_ENV from the modem 310. The supply modulator 340 may be driven in the tracking mode corresponding to one of the ET mode and the APT mode based on the average power signal D_REF and the analog envelope signal A_ENV thus provided and may generate the dynamically variable output voltage. Also, the supply modulator 340 may supply the generated output voltage to the power amplifier PA as the power supply voltage.

In an embodiment, when the power supply voltage of a fixed level is applied to the power amplifier PA, power efficiency of the power amplifier PA may decrease. Accordingly, to efficiently manage a power of the power amplifier PA, the supply modulator 340 may modulate an input voltage (i.e., a power provided from a battery) based on at least one of the analog envelope signal A_ENV and the average power signal D_REF and may provide the modulated voltage to the power amplifier PA as the power supply voltage.

The antenna ANT may transmit the RF output signal RF_OUT frequency-separated by the duplexer 330 to the outside or may provide the RF receive signal RF_R received from the outside to the duplexer 330. For example, the antenna ANT may include, but is not limited to, an array antenna.

For reference, each of the modem 310, the RFIC 320, the power amplifier PA, the duplexer 330, and the supply modulator 340 may be implemented individually as an IC, a chip, or a module. Moreover, the modem 310, the RFIC 320, the power amplifier PA, the duplexer 330, and the supply modulator 340 may be mounted together on a printed circuit board (PCB). However, embodiments of the present disclosure are not limited thereto. In some embodiments, at least part of the modem 310, the RFIC 320, the duplexer 330, and the supply modulator 340 may be implemented with a single communication chip.

In addition, the wireless communication device 300 illustrated in FIG. 20 may be included in a wireless communication system that uses a cellular network such as 5G, LTE and may also be included in a wireless local area network (WLAN) system or any other wireless communication system. A configuration of the wireless communication device 300 is not limited to the embodiment illustrated in FIG. 1 and may be variously configured in compliance with a communication protocol or a communication scheme.

The above description refers to detailed embodiments for carrying out the present disclosure. Embodiments in which a design is changed simply or which are easily changed may be included as well as an embodiment described above. In addition, technologies that are easily changed and implemented by using the above embodiments may be included in the present disclosure. Accordingly, it will be apparent to those of ordinary skill in the art that various changes and modifications may be made to the above embodiments without departing from the spirit and scope of the present disclosure as set forth in the following claims.

According to an embodiment of the present disclosure, an N-WAY coupler and a chip including the same may be provided.

While the present disclosure has been described with reference to example embodiments thereof, it will be apparent to those of ordinary skill in the art that various changes and modifications may be made thereto without departing from the spirit and scope of the present disclosure as set forth in the following claims.

What is claimed is:

1. A coupler comprising:
a plurality of unit circuits connected to a plurality of differential line pairs and a single-ended line; and
a plurality of isolation resistors connected between the plurality of differential line pairs,
wherein each unit circuit of the plurality of unit circuits comprises:
a transformer comprising a primary side connected to one differential line pair among the plurality of differential line pairs, and a secondary side connected to the single-ended line, and
a secondary-side capacitor connected in parallel to the secondary side.

2. The coupler of claim 1, wherein N is a number of the plurality of differential line pairs, and N is a natural number greater than or equal to 2.

3. The coupler of claim 2, wherein a number of the plurality of unit circuits is N.

4. The coupler of claim 1, wherein each unit circuit of the plurality of unit circuits further comprises a primary-side capacitor connected in parallel to the primary side.

5. The coupler of claim 1, wherein an impedance of each isolation resistor of the plurality of isolation resistors has a magnitude that is the same as a magnitude of a differential characteristic impedance defined in the one differential line pair.

6. The coupler of claim 1, wherein the plurality of isolation resistors comprises:
a plurality of first isolation resistors connected to a first differential line in the one differential line pair; and
a plurality of second isolation resistors connected to a second differential line in the one differential line pair.

7. The coupler of claim 1, wherein the transformer has a turn ratio of 2:1.

8. The coupler of claim 1, wherein the transformer is configured such that a bias current flows through a center tap.

9. A chip comprising:
a plurality of amplifiers configured to output a plurality of amplification signals through a plurality of differential line pairs; and
a coupler connected to the plurality of differential line pairs and configured to combine the plurality of amplification signals and to output a combined signal through a single-ended line,
wherein the coupler comprises a plurality of unit circuits connected to the plurality of differential line pairs and the single-ended line, and a plurality of isolation resistors connected between the plurality of unit circuits and the plurality of differential line pairs, and
wherein each unit circuit of the plurality of unit circuits comprises:
a transformer comprising a primary side connected to one differential line pair among the plurality of differential line pairs, and a secondary side is connected to the single-ended line, and
a secondary-side capacitor connected in parallel to the secondary side.

10. The chip of claim 9, wherein N is a number of the plurality of amplifiers, and the N is a natural number greater than or equal to 2.

11. The chip of claim 10, wherein a number of the plurality of unit circuits is N.

12. The chip of claim 10, wherein each unit circuit of the plurality of unit circuits further comprises a primary-side capacitor connected in parallel to the primary side.

13. The chip of claim 12, wherein the secondary-side capacitor has capacitance that is twice a sum of capacitance of the primary-side capacitor and a parasitic capacitance of one amplifier of the plurality of amplifiers.

14. The chip of claim 9, wherein an impedance of each isolation resistor of the plurality of isolation resistors is has a magnitude that is the same as a magnitude of a differential characteristic impedance defined in the one differential line pair.

15. The chip of claim 9, wherein the plurality of isolation resistors comprises:
a plurality of first isolation resistors connected to a first differential line in the one differential line pair; and
a plurality of second isolation resistors connected to a second differential line in the one differential line pair.

16. The chip of claim 9, wherein the transformer is configured such that a bias current flows through a center tap, and the bias current is configured to bias the plurality of amplifiers.

17. A chip comprising:
a coupler connected between a plurality of differential line pairs and a single-ended line, and configured to distribute one signal applied through the single-ended line into a plurality of signals; and
a plurality of amplifiers connected to the plurality of differential line pairs and configured to amplify the plurality of signals,
wherein the coupler comprises a plurality of unit circuits connected to the plurality of differential line pairs and the single-ended line, and a plurality of isolation resistors connected between the plurality of unit circuits and the plurality of differential line pairs, and
wherein each of the plurality of unit circuits comprises:
a transformer comprising a primary side is connected to one differential line pair among the plurality of differential line pairs and a secondary side is connected to the single-ended line, and
a secondary-side capacitor connected in parallel to the secondary side.

18. The chip of claim 17, wherein N is a number of the plurality of amplifiers, and N is a natural number greater than or equal to 2.

19. The chip of claim 17, wherein each of the plurality of unit circuits further comprises a primary-side capacitor connected in parallel to the primary side.

20. The chip of claim 17, wherein the plurality of isolation resistors comprises:
a plurality of first isolation resistors connected to a first differential line in the one differential line pair; and
a plurality of second isolation resistors connected to a second differential line in the one differential line pair.
